(19) United States
(12) Patent Application Publication
(10) Pub. No.: US 2025/0207240 A1
(43) Pub. Date: Jun. 26, 2025

(54) SYSTEMS AND METHODS FOR UNIFORM COATING OF ROLLING SPHERES

(71) Applicant: Lawrence Livermore National Security, LLC, Livermore, CA (US)

(72) Inventors: Sergei O. KUCHEYEV, Oakland, CA (US); James Barrett MERLO, Livermore, CA (US); Nicholas L. HASH, Livermore, CA (US); Chuck HEINBOCKEL, Walnut Creek, CA (US); Gregory Vincent TAYLOR, Livermore, CA (US); Rhyan Lindsay REYNOLDS, Livermore, CA (US)

(21) Appl. No.: 18/393,836

(22) Filed: Dec. 22, 2023

(51) Int. Cl. C23C 14/50; C23C 14/22

(52) U.S. Cl. CPC C23C 14/505; C23C 14/223

(57) ABSTRACT

The present disclosure relates to an apparatus for coating rollable elements. The apparatus may have a coating subsystem for generating a coating material, and a conical, dish-like element or an array of rotating rods for supporting the rolling elements thereon for rolling motion during a coating process during which the rolling elements receive the coating material. The conical dish-like element has a plurality of spaced apart track elements for supporting the rolling elements thereon. The array of rods has a plurality of spaced apart grooves for supporting the rolling elements. The openings between track elements or rotating rods allow for particulates and/or contaminants to pass during the coating process.

### FEDERALLY SPONSORED RESEARCH OR DEVELOPMENT

This invention was made with Government support under Contract No. DE-AC52-07NA27344 awarded by the United States Department of Energy. The Government has certain rights in the invention.

### FIELD

The present disclosure relates to coating of rollable objects or substrates, and more particularly to systems and methods for forming a uniform coating on rollable objects or substrates that avoids issues with contamination and non-uniformity of coatings typically present when forming a coating in a rolling manner in a traditional curved or straight walled pan or pan-like component.

### BACKGROUND

The statements in this section merely provide background information related to the present disclosure and may not constitute prior art.

Uniform coating of spherical substrates is a major challenge that limits applications such as inertial confinement fusion. Conventionally, spherical substrates have been coated by vapor deposition techniques while multiple spheres are rolled in a pan with dish-shaped or straight wall geometry. FIG. 1 shows a prior art plasma polymerization system 10 for coating rolling elements 12, in this example spherical substrates, using a dish shaped pan “P” (FIG. 1). This approach involves a subsystem “S” including a reactor vessel “R” and a coil “C” that forms a coating subsystem. The coating subsystem generates a plasma made up of an electrically excited gas (e.g., argon working gas and precursor molecules) that coats the rolling or spherical substrates supported on the pan P.

The above-described approach has serious limitations. For one, during the coating process, rolling or bouncing spheres can touch, collide, and experience slipping interaction leading to material wear and contamination of the coating with particulates. Another limitation is that rolling spheres do not allow the collimation of depositing species flux since the position of the spheres is continuously changing during deposition. Still further, another limitation is that conventional pans can trap particulates in the region where spheres are rolling, and this could lead to the formation of coating defects.

### SUMMARY

This section provides a general summary of the disclosure, and is not a comprehensive disclosure of its full scope or all of its features.

In one aspect, the present disclosure relates to a vapor deposition apparatus for coating rollable elements. The apparatus may comprise a coating subsystem for generating a coating material. A conical, dish-like element may be included for supporting the rolling elements thereon for rolling motion during a coating process while the rolling elements receive the coating material. The conical dish-like element may include a plurality of spaced apart track elements for supporting the rolling elements thereon. The track elements define openings between adjacent ones of the track elements through which particulates and/or contaminants may pass during the coating process.

In another aspect, the present disclosure relates to a vapor deposition apparatus for coating rollable elements. The apparatus may comprise a coating table having a plurality of rotationally mounted, generally parallel arranged and spaced apart rods. The rods support thereon the rollable elements to enable the rollable elements to be subjected to vapor deposition of a material thereon. A driving subsystem may be included for simultaneously driving the rods rotationally. The rods may each include features for maintaining each of the rollable elements in a constant longitudinal position on a given one of the rods, such that a constant longitudinal spacing is maintained between adjacent ones of the rollable elements located on each said rod.

In still another aspect, the present disclosure relates to a vapor deposition coating method for uniformly covering rollable elements with a coating. The method may comprise using a conical dish-like element with a plurality of spaced apart, circumferential tracks to support the rollable elements thereon in a spaced apart configuration. The method may further include positioning the conical dish-like element at an angle such that a wall portion of the conical dish-like element is generally horizontal. The method may further involve rotation of the conical dish-like element to cause rotation of the rollable elements while exposing the rollable elements to depositing species flux. In this manner, the rollable elements are prevented from contacting one another while the conical dish-like element is being rotated, which causes a uniform coating to be formed on each one of the rollable elements.

In still another aspect, the present disclosure relates to a vapor deposition coating method for uniformly covering rollable elements with a vapor deposited coating. The method may comprise using a planar coating table having a plurality of spaced apart, rotationally supported rods to support the rollable elements thereon in a spaced apart configuration, and such that each said rollable element is supported by an adjacent pair of the plurality of spaced apart, rotationally supported rods. The method may further include using a driving subsystem to drive the rods rotationally in a common rotational direction. While the rods are being driven rotationally, the rollable elements are exposed to a vapor deposition operation to cause the rollable elements to be uniformly covered with a coating.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustrative purposes only of selected embodiments and not all possible implementations, and are not intended to limit the scope of the present disclosure.

Corresponding reference numerals indicate corresponding parts throughout the several views of the drawings.

FIG. 1 is an isometric illustration of a perfluoro-2-butene (PFB) plasma polymerization coating process using a helical resonator and a conventional dish shaped pan for coating spherical structures;

FIG. 2 is a perspective view of a dish element in accordance with one embodiment of the present disclosure, where the dish element includes a plurality of circumferential, spaced apart track elements having an inverted “V” shape for each of the track elements;

FIG. 3 is a perspective view of a dish element in accordance with another embodiment of the present disclosure, where the dish element includes a plurality of circumferential, spaced apart track elements, and where each track element has a rounded upper edge surface;

FIG. 4 is a highly enlarged view of a portion of the dish element of FIG. 3 showing the randomizing features and randomizing motion bar carried by the dish element;

FIG. 5 is an isometric view of the dish element of FIG. 4 with a surface portion of the dish element omitted to show the randomizing motion bar;

FIG. 6 is an isometric view of a vapor deposition apparatus in accordance with one embodiment of the present disclosure, where the vapor deposition apparatus incorporates a planar coating table for supporting rollable elements thereon;

FIG. 7 is an overhead plan view of the coating table of the apparatus of FIG. 6 showing how the coating table supports the rollable elements in a uniformly spaced arrangement;

FIG. 8 is a perspective view of one of the rods that make up the coating table shown in FIGS. 6 and 7;

FIG. 9 is a highly enlarged perspective view of a portion of the coating table showing a plurality of rolling elements supported thereon; and

FIG. 10 is another embodiment of a vapor deposition apparatus of the present disclosure which incorporates a collimator and plasma shield for enclosing the coating table.

### DETAILED DESCRIPTION

Example embodiments will now be described more fully with reference to the accompanying drawings.

The present disclosure relates to systems and methods which enable a uniform coating to be applied to spherical substrates by at least one of spraying or vapor deposition techniques. The various systems and methods described herein enable the following: random rotation of rolling elements, draining of particulates, collimation of depositing species flux, and limiting the deposition of the coating onto the substrate holder surfaces. These qualities and features serve to dramatically reduce or completely eliminate substrate-substrate interaction during deposition and enable controlling of depositing species impact angles and the temperature of the substrates via radiative heating during the fabrication process.

FIG. 2 illustrates a conical element or dish element 100 (hereinafter simply “dish” 100) that can be used in the system 10 to overcome the myriad drawbacks that the conventional pan P suffers from when coating rolling elements. The dish 100 in this example may be directly substituted into the system 10 shown in FIG. 1 to form a new system which does not suffer from the above-described drawbacks that result from using the conventional pan P.

The dish in some embodiments may be made from stainless steel, aluminum and copper alloys, molybdenum, or other suitable materials, and has a main dish portion 102 and a tubular neck portion 104. The neck portion 104 enables mounting of the dish 100 to an electric motor and/or PZT vibrator 12 (FIG. 1), by which a rotational driving force can be applied to the dish 100 to drive the dish rotationally during a coating operation being carried out by the system 10.

The main portion 102 of the dish 100 has a wall portion 106 having a conical configuration that merges into a central bottom portion 108. The wall portion 106 may be generally flat or may have a slight curvature. In some embodiments, the wall portion 106, when viewed from the side, forms an angle of about 120 degrees (i.e., one side of the wall portion 106 in this example extends at an angle of about 30 degrees relative to a horizontal axis running parallel to the central bottom portion 108).

The wall portion 106 is formed by a plurality of circumferential, concentrically arranged, spaced apart track elements 110. With the dish 100, the track elements 110 have an inverted “V” shape defined in part by an uppermost edge 110a of each track, and a pair of sidewalls of 110b of each track. The track elements 110 in this example are integrally formed with radially extending support sections 112 and such that open channels 114 are formed between adjacent ones of the elements 110. In some embodiments the track elements 110 may be formed separately and secured to the support sections 112 by adhesives, fasteners or other means, to form the dish 100.

During operation, the track elements 110 enable the dish 100 to be supported such that one side of the dish is generally parallel to a horizontal axis; as such, rotational motion of the dish 100 will enable the rolling elements 12 being coated to make two points of contact, one with each of the two facing sidewalls 110b of each adjacent pair of the track elements 110. The rolling elements 12 thus will roll on the sidewalls 110b of adjacent facing pairs of the track elements 110 such that the rolling elements remain located in a generally constant, non-changing location. This prevents bouncing as well as rubbing or sliding of any two or more of the rolling elements 12 against one another. This also keeps each rolling element in the same physical location during deposition. The rolling elements 12 themselves may be spherically shaped, or egg-shaped, or take any other shape that is capable of being rolled. Powder particles and optical elements may form the rolling elements as well, provided they are able to be rolled.

The channels 114 formed between the track elements 110 enable particulate contaminants to be drained from dish 100 during a coating operation, and thus eliminate contamination with the sidewalls 110b of the track elements 110 as well as eliminate the possibility of contamination with the rolling elements 12 being coated. The width of the channels 114 may vary significantly, in part due to the size and/or shape of the rolling elements being coated, but in some embodiments the width may be between about 0.1 mm to about 1.5 mm. A threaded fastener 118 may be engaged with a threaded bore (not visible) in an end of the neck portion 104 to simplify the manufacturing process of the dish and to enable easy assembly and removal of the main portion of the dish 102 from the neck portion 104.

The dish 100 illustrated in FIG. 2 in some embodiments also includes a plurality of radially separated holes 120. The holes 120 communicate with projections 124 of a motion randomizing bar 122 housed in a radially extending channel (not visible in FIG. 2) in the main dish portion 102. The projections 124 project just proud of the support sections 112 and contact the rolling elements 12, once for every 360 degree revolution of the dish 100, as the dish 100 rotates. This helps to randomize rolling motion of the rolling elements 12 as the rolling elements are rolling in contact with the sidewalls 110b of the track elements 110.

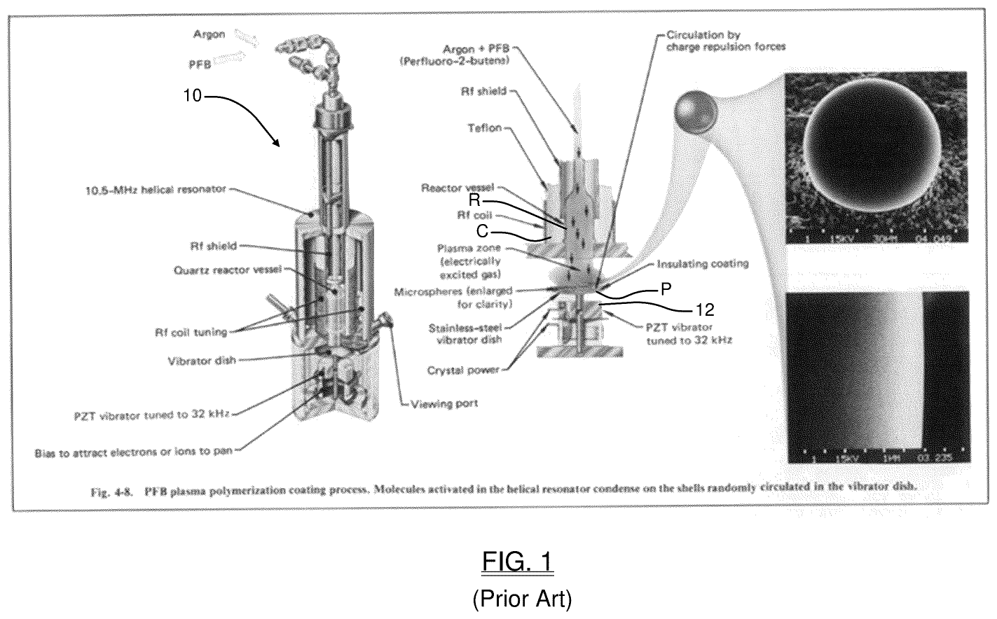

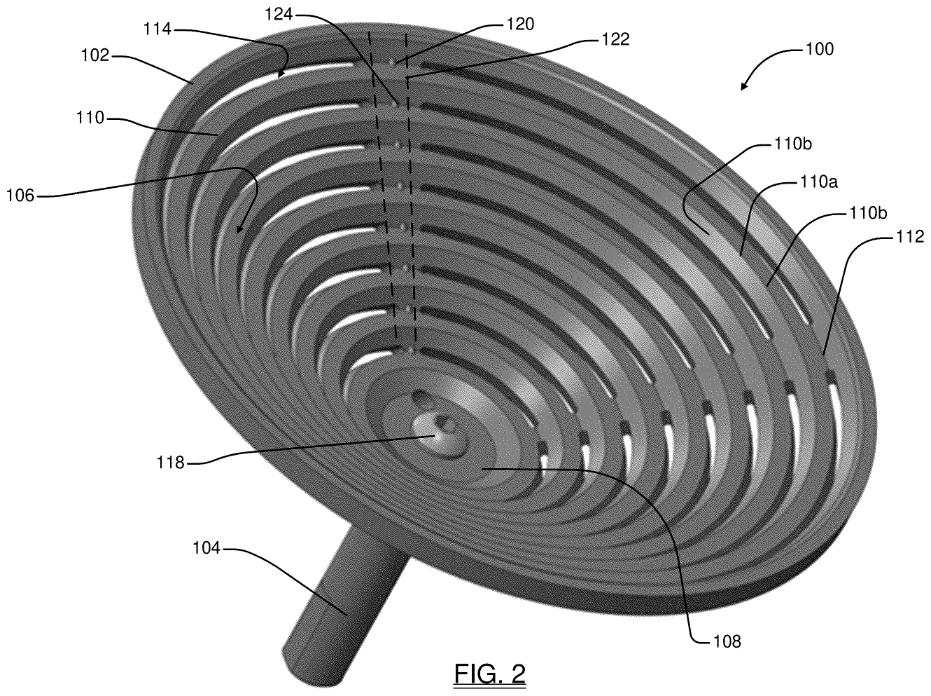

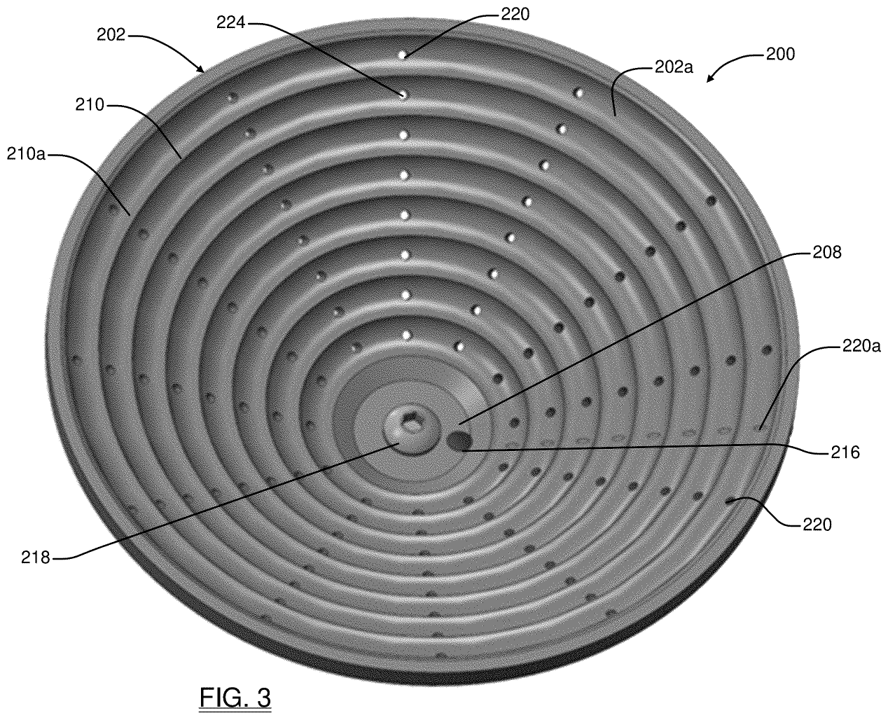

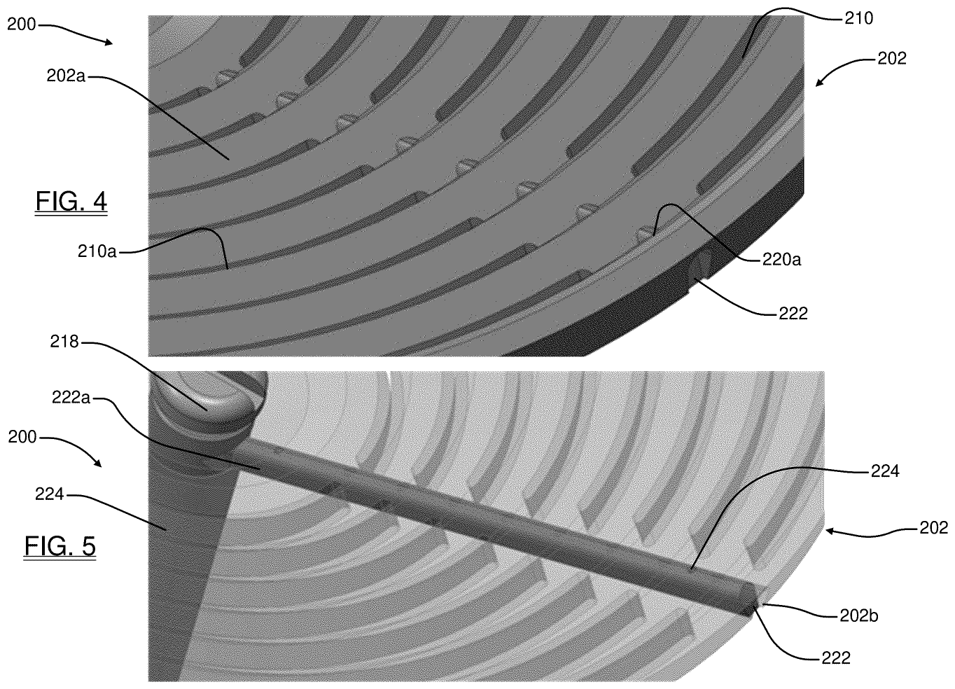

FIG. 3 shows a dish 200 in accordance with another embodiment of the present disclosure. Components in common with the dish 100 are represented by reference numbers increased by 100 over those used to describe the dish 100. The dish 200 in this example similarly includes a main dish portion 202 and a neck portion (not visible) like the dish 100, as well as a plurality of circumferential, concentrically arranged and spaced apart track elements 210. In this example, however, the track elements 210 each have a rounded upper edge 210a versus the sharp edge 110a of the dish 100, and each track element projects upwardly out from a bottom wall portion 202a of the main dish portion 202. As such, there are no open slots between the track elements 210 for draining particulates. Instead, the main dish portion 202 includes a plurality of radially arranged groups of holes 220 through which particulates can be drained. Referring to FIGS. 3-5, one group of holes 220a receives projections 224 from a randomizing motion element 222. In this example the randomizing element 222 forms a rod-like or bar-like component (hereinafter simply “randomizing motion bar” 222). The randomizing motion bar 222 is seated within a radially extending bore 202b which has a cross-sectional shape which is keyed to the cross-sectional shape of the randomizing motion bar 222. One example of the cross-sectional shape of the randomizing motion bar 222 is shown in FIGS. 4 and 5. Other keyed cross-sectional shapes could just as easily be used; the requirements being that the randomizing motion bar 222 does not fall out of the dish and is not able to rotate relative to the main dish portion 202. The randomizing motion bar 222 operates in the same manner as bar 122 to help randomize the motion of rolling elements 12 as they travel on the track elements 210. A distal end 222a of the randomizing motion bar may be secured to a neck portion 224 of the dish 200 in any suitable manner, such as by a set screw, adhesives, etc., or it can be secured by the force of the screw 218 in a notch in the shaft 224.

An important advantage of both the dish 100 and the dish 200 is that each is easily, readily retrofittable into the system 10 shown in FIG. 1 with little to no modification being required of the system 10. The dishes 100 and 200 each significantly reduce or completely eliminate contact between the rollable elements 12 during a plasma polymerization process being carried out with the system 10, as well as allow particulates and contaminants to be quickly removed from the dish 100 or 200 such that same do not contaminate the rollable elements. Still further, a collimator can be added above each dish 100 or 200, with a flux limiting aperture being provided to allow depositing species flux only in defined regions above each rolling element.

The dishes 100 and 200 are both well suited for simultaneously coating a plurality of the rolling elements, in one specific example eight spherical substrates with a diameter of 2 mm each. In one embodiment, the coating may be accomplished using a deposition source that outputs uniform flux of particles over an area of about 3×40 square mm. However, the dishes 100 and 200 are not limited to only eight 2-mm-diameter substrates, but rather the dishes 100 and 200 are each easily scalable, with dimensions determined largely by the maximum number of spherical substrates to be coated simultaneously, the substrate diameter, and the deposition source size.

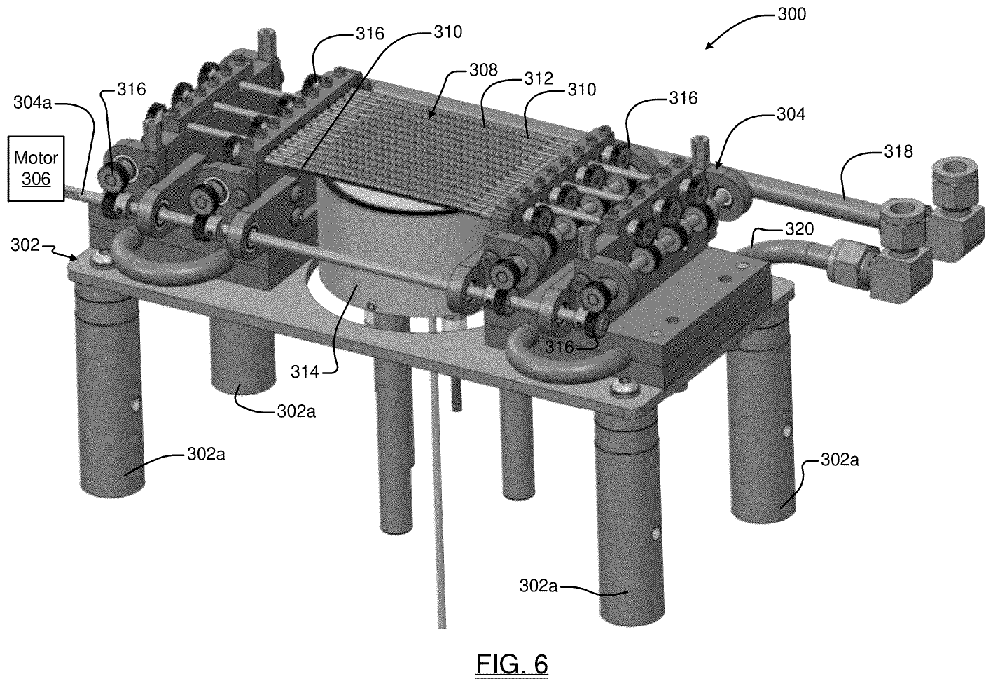

Referring now to FIG. 6, a system 300 is shown for coating rolling objects with a vapor deposition technique. A frame/table 302 having a plurality of legs 302a is used to support a gear mechanism 304. The gear mechanism 304 has an input shaft 304a which is in communication with an output shaft of a prime mover. In this example, the prime mover is a motor 306. However, the system 300 is not limited to use with only motors, and any component or system which is able to drive the gear mechanism 304 may be used.

The system 300 in this example also includes a coating table 308 made up of a plurality of spaced apart, parallel arranged, rotationally supported rods 310. In some embodiments, the coating table 308 forms a planar coating table. The rods 310 are all driven in the same rotational direction by the gear mechanism 304. The rods 310 support rolling elements 312 thereon. In this example the rolling elements 312 are shown as spherical objects, but virtually any object which is capable of being rolled could be coated using the system 300. The rolling objects 312 are subjected to a vapor deposition operation while being rolled on the rods 310.

The system 300 also may optionally include an in-vacuum heater 314 for heating the rolling objects 312 during a vapor deposition operation. The gear mechanism 304 in this example includes a plurality of gears 316 which are configured to drive the rods 310 all in the same rotational direction from the motive force provided by an output shaft of the motor 306. Coolant lines 318 and 320 may be integrated into the gear mechanism 304 to circulate a coolant to help cool the gears when the rolling elements are being heated during a vapor deposition operation.

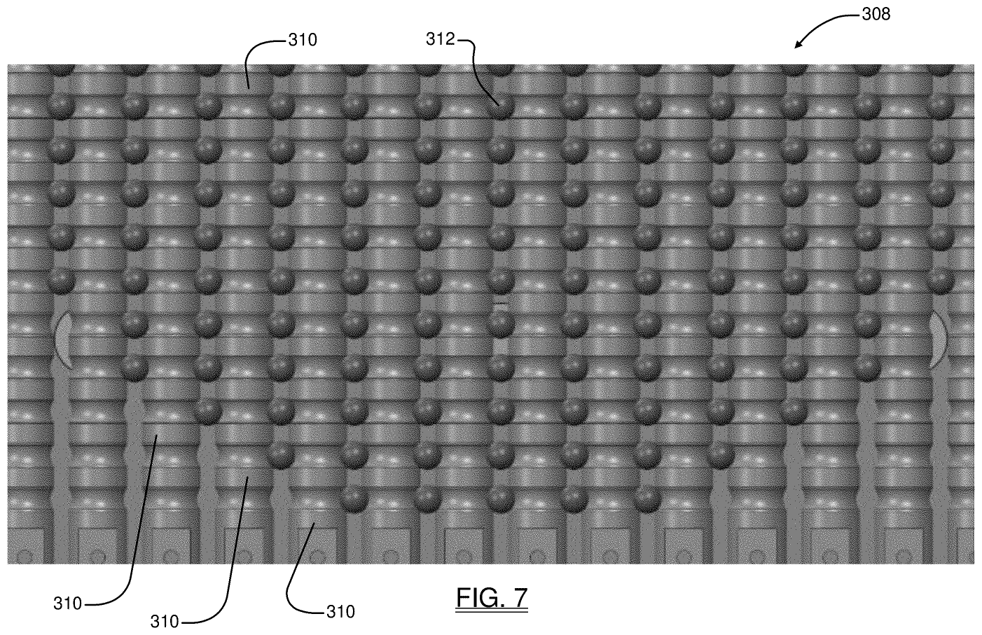

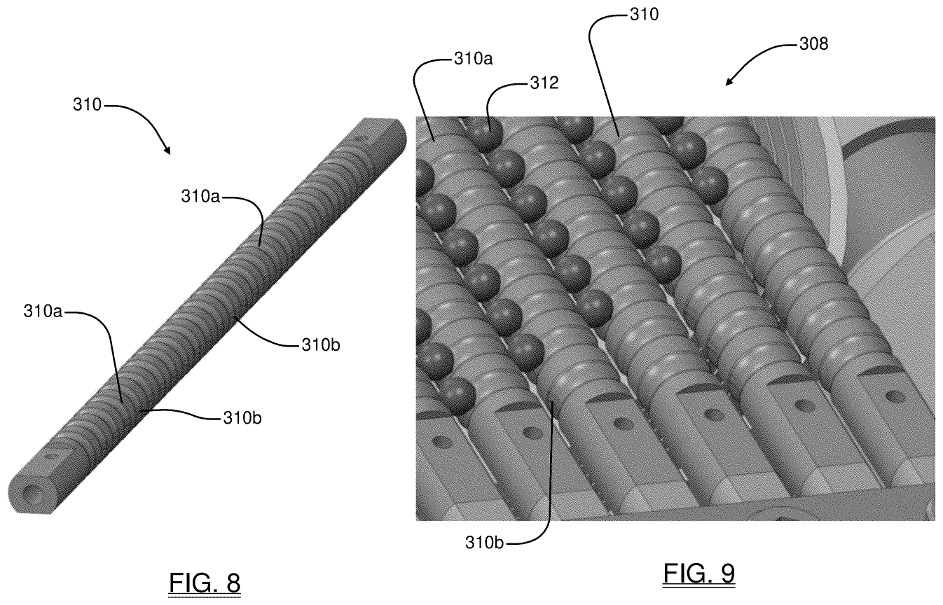

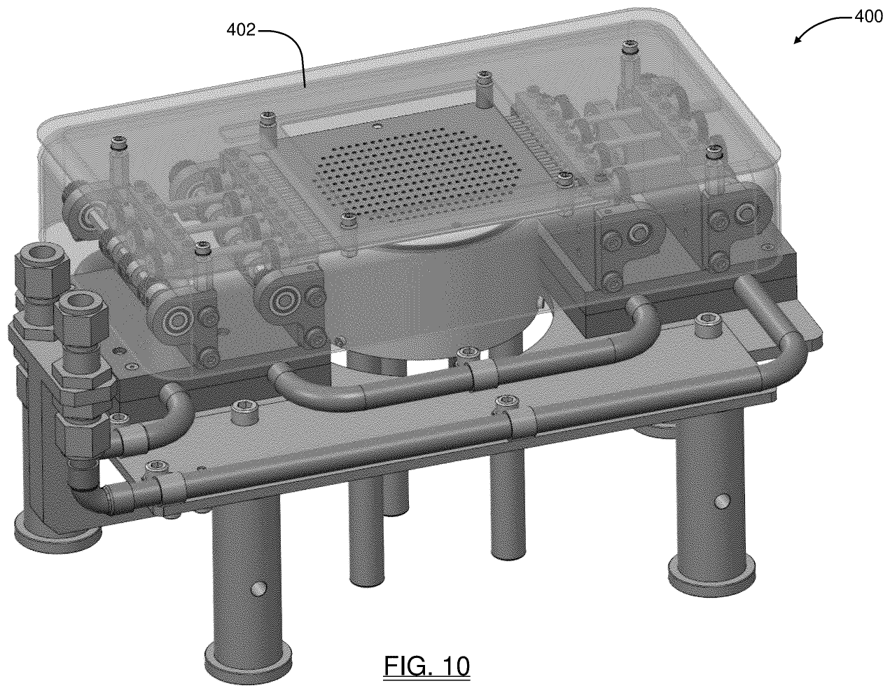

With brief reference to FIGS. 7 and 9, the construction of the coating table 308 can be seen in greater detail. FIG. 8 shows an isometric view of just one of the rods 310. In FIGS. 8 and 9, it can be seen that the rod 310 includes a plurality of evenly spaced apart circumferential grooves 310a formed thereon, as well as a plurality of spaced apart protrusions 310b. The rods 310 may be formed from any suitable material, but in some embodiments are typically formed from stainless steel, copper or aluminum alloys, or molybdenum. The grooves 310a help to keep the rolling elements 312 “stationary” and spaced apart while the rods 310 rotate. By “stationary” in this context it is meant that the rolling elements 312 do not move longitudinally along the rod 310 but rather remain at their defined longitudinal locations on the rod (i.e., defined by the specific groove 310a that each rolling element 312 is engaged with). The protrusions 310b serve to act as a “randomizing” feature to help randomize the orientations of the rolling elements 312 as the rolling elements hit the protrusions and are slightly, momentarily jarred while the rods 310 are rotating. This randomizing action happens for every rotation of the rods 310. In this regard it will be appreciated that not every rod 310 needs to include the protrusions 310b, and it is preferred that every other rod 310 that makes up the coating table 308 does not include the protrusions 310b. In this manner, there will be no chance of a rolling element 312 being pinched by the protrusions 310b, which might possibly occur if two adjacent rods 310 both having the protrusions 310b rotated towards and past one another.

The rods 310 of the coating table 308 thus enable a relatively large plurality of rolling elements 312 to be subjected to a vapor deposition operation with the risk of the rolling elements 312 touching one another. The spacings between the rods 310 also enables particulates and contaminants that might be present during a coating operation to fall through the coating table 308, and thus further eliminates the risk of contamination of the rolling objects 312 during a vapor deposition process.

With brief reference to FIG. 10, a vapor deposition system 400 in accordance with another embodiment of the present disclosure is shown. In this example the system 400 is similar to the system 300 shown in FIG. 6, but further includes a collimator and plasma shield 402. This enables controlling depositing species flux and limiting the deposition onto the internal components of the system 100. The collimator and plasma 402 shield may be formed from various materials but is typically formed from stainless steel or molybdenum, depending on the desired substrate temperature during deposition. The geometry and size of the openings in the collimator can be selected for a desired balance between the degree of depositing species flux collimation and the deposition rate. In one embodiment, the system 400 may simultaneously coat 281 rolling elements (e.g., spherical substrates), and is readily scalable to accommodate simultaneously coating a greater or lesser number of rolling elements. The systems 300 or 400 in some embodiments support the rolling elements (e.g., spherical elements) in a two-dimensional grid arrangement, where each spherical element has a diameter of 2 mm, with a deposition source that outputs uniform flux of particles over a circular area of about 75 mm in diameter.

The various embodiments and methods disclosed herein enable the coating of virtually any rollable object, while eliminating, or virtually eliminating, the possibility of contact of the objects during the coating process. The systems and methods disclosed herein also enable contaminants and particulates to be kept out of contact with the rolling elements being coated and removed from the environment where the coating is occurring. The systems and methods are readily scalable to be able to accommodate simultaneously coating a large number of rolling objects, and thus can potentially aid in reducing the overall cost of the coating process. The various embodiments described herein are expected to find particular utility in fabricating various elements including, without limitation, ablator fuel capsules for inertial confinement fusion applications, as well as other high-value applications requiring rollable objects such as spheres, jewelry objects, metrological standards, ball bearings, and even optical elements.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Example embodiments are provided so that this disclosure will be thorough, and will fully convey the scope to those who are skilled in the art.

Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items. As used herein, the term “about”, when used immediately previous to a specific recited value, denotes the specific recited value as well as all values, inclusive, from +/−10% of the specific recited value.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. An apparatus for coating rollable elements, the apparatus comprising:
a coating subsystem for generating a coating material;
a conical, dish-like element for supporting the rolling elements thereon for rolling motion during a coating process while the rolling elements receive the coating material;
the conical dish-like element including:
a plurality of spaced apart track elements for supporting the rolling elements thereon; and
the track elements defining openings between adjacent ones of the track elements through which particulates and/or contaminants may pass during the coating process.

2. The apparatus of claim 1, wherein the track elements comprise circumferential track elements.

3. The apparatus of claim 2, wherein the circumferential track elements having an inverted V-shape.

4. The apparatus of claim 2, wherein the circumferential track elements having a rounded upper edge.

5. The apparatus of claim 1, wherein the conical dish-like element forms a has a main dish portion forming an angle of 120 degrees.

6. The apparatus of claim 1, wherein the conical dish-like element further includes a main dish portion and a neck portion, the track elements being located on the main dish portion and the neck portion projecting from the main dish portion and adapted to receive a rotational force to enable the main dish portion to be rotated during the coating process.

7. The apparatus of claim 1, wherein the conical dish-like element further includes:
a plurality of openings; and
a randomizing motion element carried on the conical dish-like element, and having protrusions which project through the plurality of openings, the plurality of protrusions configured to randomize motion of the rolling elements as the rolling elements impact the protrusions while the conical dish-like element is being rotated during the coating process.

8. The apparatus of claim 7, wherein the dish-like element includes radially extending channel, and the randomizing motion element is held within the radially extending channel in a keyed arrangement.

9. A vapor deposition apparatus for coating rollable elements, the apparatus comprising:
a coating table having a plurality of rotationally mounted, generally parallel arranged and spaced apart rods, the rods supporting thereon the rollable elements to enable the rollable elements to be subjected to vapor deposition of a material thereon;
a driving subsystem for simultaneously driving the rods rotationally; and
the rods each including features for maintaining each of the rollable elements in a constant longitudinal position on a given one of the rods, such that a constant longitudinal spacing is maintained between adjacent ones of the rollable elements located on each said rod.

10. The apparatus of claim 9, wherein the features comprise grooves.

11. The apparatus of claim 9, wherein the coating table forms a planar coating table.

12. The apparatus of claim 9, wherein select ones of the rods each include a plurality of longitudinally spaced apart randomizing features for randomizing rotation of the rollable elements supported on each rod during rotation of the rods.

13. The apparatus of claim 12, wherein the randomizing features comprise protrusions.

14. The apparatus of claim 9, wherein the rods are driven rotationally in the same direction.

15. The apparatus of claim 9, wherein the driving subsystem comprises a collection of gears driven by a motor.

16. The apparatus of claim 15, further comprising a plurality of cooling lines for flowing a coolant to cool the collection of gears.

17. The apparatus of claim 9, further comprising a collimator and plasma shield shaped to be positioned over the coating table.

18. The apparatus of claim 9, wherein the rods are evenly spaced from one another and all rotated in the same rotational direction.

19. A vapor deposition coating method for uniformly covering rollable elements with a coating, the method comprising:
using a conical dish-like element with a plurality of spaced apart, circumferential tracks to support the rollable elements thereon in a spaced apart configuration;
positioning the conical dish-like element at an angle such that a wall portion of the conical dish-like element is generally horizontal; and
rotating the conical dish-like element to cause rotation of the rollable elements while exposing the rollable elements to depositing species flux, such that the rollable elements are prevented from contacting one another while the conical dish-like element is being rotated, to cause a uniform coating to be formed on each one of the rollable elements.

20. A vapor deposition coating method for uniformly covering rollable elements with a vapor deposited coating, the method comprising:
using a planar coating table having a plurality of spaced apart, rotationally supported rods to support the rollable elements thereon in a spaced apart configuration, and such that each said rollable element is supported by an adjacent pair of the plurality of spaced apart, rotationally supported rods; and
using a driving subsystem to drive the rods rotationally in a common rotational direction; and
while the rods are being driven rotationally, exposing the rollable elements to a vapor deposition operation to cause the rollable elements to be uniformly covered with a coating.
